(19) United States
(12) Patent Application Publication
(10) Pub. No.: US 2014/0061880 A1
(43) Pub. Date: Mar. 6, 2014

(54) WAFER LEVEL CHIP SCALE PACKAGE

(71) Applicant: CHIPMOS TECHNOLOGIES INC., (unknown)

(72) Inventor: TSUNG JEN LIAO, HSINCHU (TW)

(21) Appl. No.: 13/935,911

(22) Filed: Jul. 5, 2013

(30) Foreign Application Priority Data
Aug. 31, 2012 (TW) 101131684

(51) Int. Cl. H01L 21/768; H01L 23/538

(52) U.S. Cl. CPC H01L 21/76894; H01L 23/5386
USPC 257/666; 438/109

(57) ABSTRACT

The present disclosure provides a semiconductor device including a semiconductor element having a first surface and a second surface, which is opposite to the first surface, and a conductive via disposed on the semiconductor element. The semiconductor element includes a die; a first redistribution layer positioned on the first surface, wherein the first redistribution layer is configured to fan out the die; and a second redistribution layer positioned on the second surface of the semiconductor element. The conductive via is configured to electrically connect the first redistribution layer and the second redistribution layer, wherein the sizes of the two ends of the conductive via are different and the die can be electrically coupled to another semiconductor device through the conductive via.

### BACKGROUND OF THE INVENTION

1. Technical Field

The present invention relates to a semiconductor package, and more particularly to a method for forming a scalable wafer level chip scale package that is capable of forming three-dimensional stacking structures.

2. Background

A 3D integrated circuit (3D IC) includes a semiconductor device with two or more layers of active electronic components integrated (e.g., vertically stacked and connected) to form an integrated circuit. Various forms of 3D IC technology are currently being developed, including die-on-die stacking, die-on-wafer stacking, and wafer-on-wafer stacking. In 3D IC technology, electronic components (e.g., integrated circuits) are built on two or more substrates and packaged to form a single integrated circuit. Vertical connections are made between the electronic components such as by the implementation of through-silicon vias (TSVs). The stacked die may then be packaged, such that of I/Os, to provide a connection to the 3D IC.

The present invention discloses an improved structure and a method for manufacturing said structure, in order to devise the redistribution layers (RDL) on the two opposite surfaces of a die or a wafer.

### SUMMARY

One embodiment of the present disclosure provides a semiconductor device including a semiconductor element having a first surface and a second surface, which is opposite to the first surface, and a conductive via disposed on the semiconductor element. The semiconductor element includes a die; a first redistribution layer positioned on the first surface, wherein the first redistribution layer is configured to fan out the die; and a second redistribution layer positioned on the second surface of the semiconductor element. The conductive via is configured to electrically connect the first redistribution layer and the second redistribution layer, wherein the sizes of the two ends of the conductive via are different and the die can be electrically coupled to another semiconductor device through the conductive via.

Another embodiment of the present disclosure provides a semiconductor device fabrication method. The method includes providing a semiconductor element having a first surface and a second surface, which is opposite to the first surface, and forming a conductive via in the semiconductor element to electrically couple the semiconductor device to another semiconductor device. The semiconductor element comprises a die, a first redistribution layer positioned on the first surface, and a second redistribution layer positioned on the second surface, and the first redistribution layer is configured to fan out the die. The conductive via is configured to electrically connect the first redistribution layer and the second redistribution layer, wherein the sizes of the two ends of the conductive via are different.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 shows a semiconductor package structure according to one embodiment of the present invention;

FIG. 2 shows a semiconductor package structure according to another embodiment of the present invention;

FIG. 3 shows a semiconductor package structure according to another embodiment of the present invention;

FIG. 4 shows a fan-out semiconductor package structure according to one embodiment of the present invention;

FIG. 5 shows a fan-out semiconductor package structure according to another embodiment of the present invention;

FIG. 6 shows a fan-out semiconductor package structure according to another embodiment of the present invention;

FIG. 7 shows a semiconductor package structure with a dry film according to one embodiment of the present invention;

FIG. 8 shows a fan-out semiconductor package structure with a dry film according to one embodiment of the present invention;

FIG. 9 shows a semiconductor stacking package structure according to one embodiment of the present invention; and

FIG. 10 shows a fan-out semiconductor stacking package structure according to one embodiment of the present invention.

### DETAILED DESCRIPTION

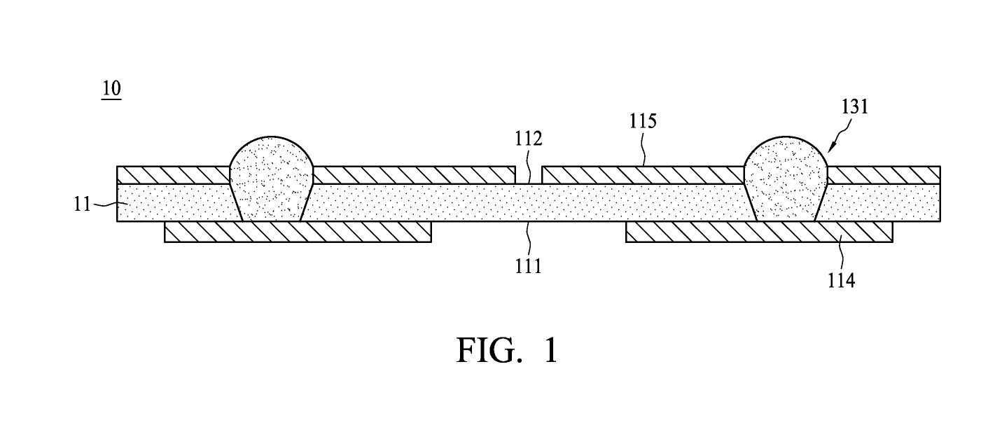

FIG. 1 shows a semiconductor device 10 according to one embodiment of the present invention, including a semiconductor element having a first surface 111 and a second surface 112. The semiconductor element possesses a semiconductor die 11, a first redistribution layer (RDL) 114 positioned on the first surface 111, and a second RDL 115 positioned on the second surface 112. A conductive via 131 is disposed on the semiconductor element, penetrating through the die 112 and the second RDL 115, and configured to electrically connect the first RDL 114 and the second RDL 115, wherein the sizes of the two ends of the conductive via 131 are different and the die can be electrically coupled to another semiconductor device (not shown) through the conductive via 131.

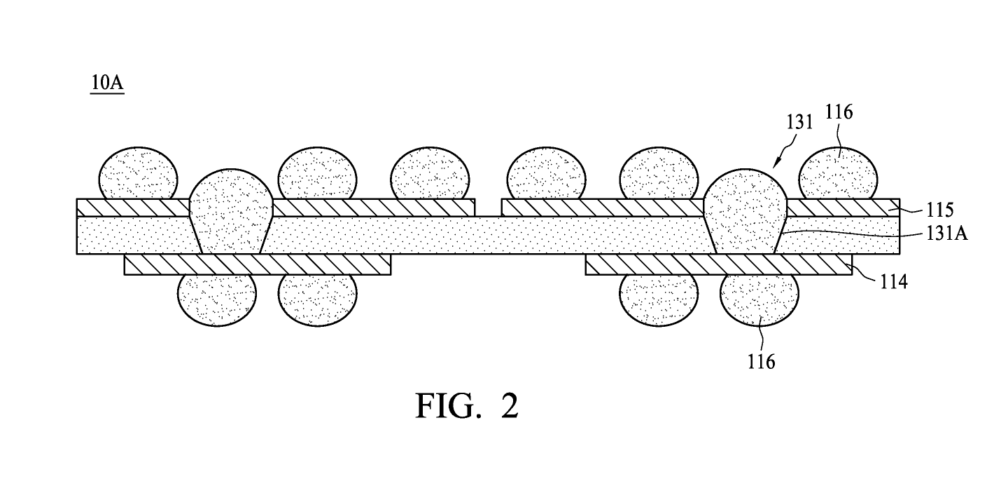

FIG. 2 shows a semiconductor device 10A according to another embodiment of the present invention. The structure of the semiconductor device 10A is similar to that of the semiconductor device 10, with additional lead connectors 116 positioned on the RDL. In the present embodiment, the lead connectors 116 can be, not in a limited way, solder balls. The lead connectors 116 are allowed to only be placed on the first RDL 114, the second RDL 115, or on both of the RDLs. The conductive via in the semiconductor device 10A shows a tapered portion 131A, in a sense that the size of the via end close to the second RDL 115 is larger than the via end close to the first RDL 114. The number of the lead connectors 116 in the semiconductor device 10A is not fixed and can be altered according to the vertical design of a three-dimensional stacking structure. In another embodiment, the conductive via 131 contains conductive materials, for example, copper, tin, lead-tin alloy, or the combination thereof. The conductive materials may fill the entire conductive via 131 or be coated on the surface of the inner wall of the conductive via 131 as long as it forms a conductive path connecting the first RDL 114 and the second RDL 115.

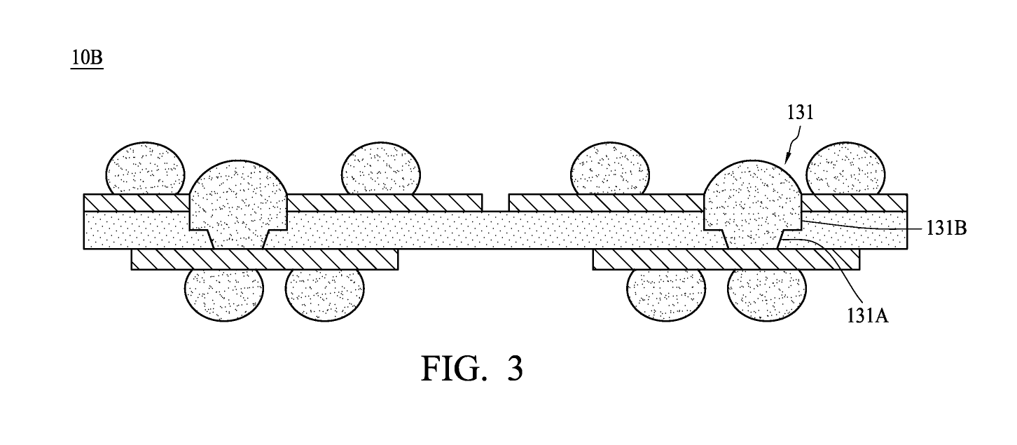

FIG. 3 shows a semiconductor device 10B according to another embodiment of the present invention. The conductive via 131 shown in FIG. 3 includes a tapered portion 131A and a planar portion 131B. The different portions of the conductive via 131 may be formed by different processes, for example, in the present embodiment, a UV laser drilling process is used to form the tapered portion 131A whereas a UV laser scanning process is subsequently implemented to form the planar portion 131B. Several etching methods, such as wet-etching, dry-etching, and reactive ion etching, which may form the desired profile, are also covered by the scope of the present invention.

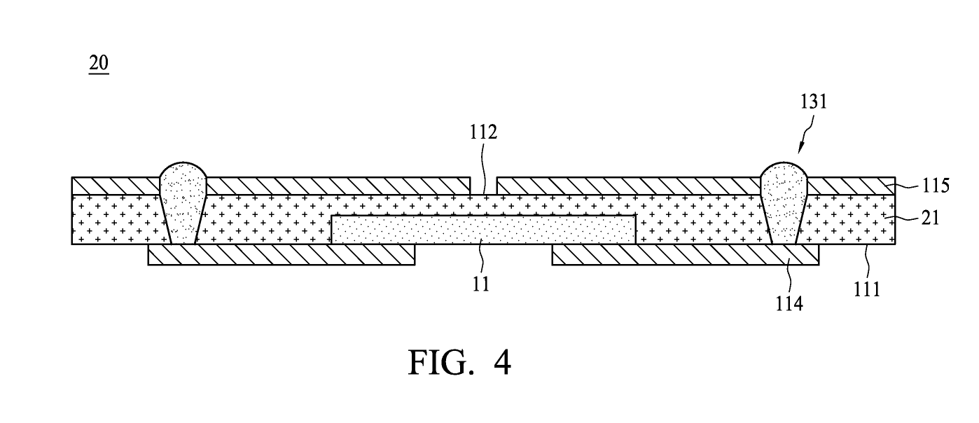

FIG. 4 shows a semiconductor device 20 according to another embodiment of the present invention. The semiconductor device 20 includes a semiconductor element having a first surface 111 and a second surface 112. The semiconductor element possesses a semiconductor die 11, a first redistribution layer (RDL) 114 positioned on the first surface 111, a second RDL 115 positioned on the second surface 112, and a molding compound 21 adjacently positioned on some surfaces of the die 11. In the present embodiment, three out of the four surfaces of the die 11 are surrounded by the molding compound 21. A conductive via 131 is disposed on the semiconductor element, penetrating through the molding compound 21 and the second RDL 115, and configured to electrically connect the first RDL 114 and the second RDL 115, wherein the sizes of the two ends of the conductive via 131 are different and the die can be electrically coupled to another semiconductor device (not shown) through the conductive via 131.

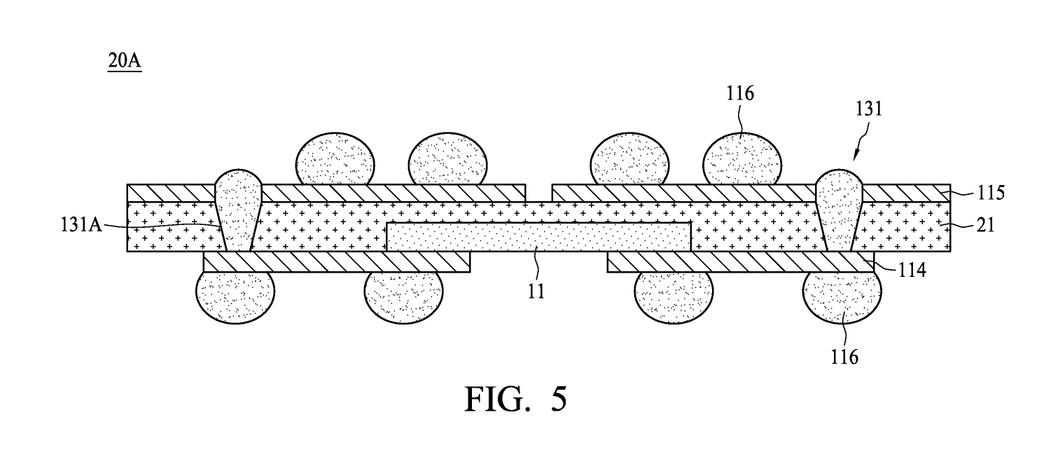

FIG. 5 shows a semiconductor device 20A according to another embodiment of the present invention. The structure of the semiconductor device 20A is similar to that of the semiconductor device 20, with additional lead connectors 116 positioned on the RDL. In the present embodiment, the lead connectors 116 can be, not in a limited way, solder balls. The lead connectors 116 are allowed to only be placed on the first RDL 114, the second RDL 115, or on both of the RDLs. The conductive via in the semiconductor device 20A shows a tapered portion 131A, in a sense that the size of the via end close to the second RDL 115 is larger than the via end close to the first RDL 114. The number of the lead connectors 116 in the semiconductor device 20A is not fixed and can be altered according to the vertical design of a three-dimensional stacking structure. In another embodiment, the conductive via 131 contains conductive materials, for example, copper, tin, lead-tin alloy, or the combination thereof. The conductive materials may fill the entire conductive via 131 or be coated on the surface of the inner wall of the conductive via 131 as long as it forms a conductive path connecting the first RDL 114 and the second RDL 115.

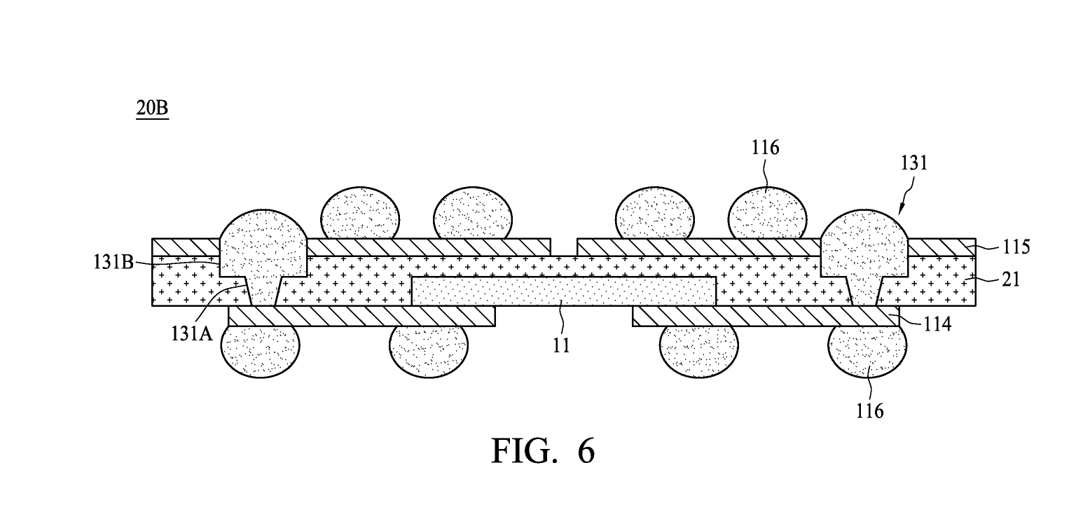

FIG. 6 shows a semiconductor device 20B according to another embodiment of the present invention. The conductive via 131 shown in FIG. 6 includes a tapered portion 131A and a planar portion 131B. The different portions of the conductive via 131 may be formed by different processes, for example, in the present embodiment, a UV laser drilling process is used to form the tapered portion 131A whereas a UV laser scanning process is subsequently implemented to form the planar portion 131B. Several etching methods, such as wet-etching, dry-etching, and reactive ion etch, which may form the desired profile, are also covered by the scope of the present invention.

The present disclosure also provides a semiconductor device fabrication method. The method includes providing a semiconductor element as shown in FIGS. 1 and 4, and forming a conductive via in the semiconductor element. The detailed steps will be addressed in the following paragraphs. Both semiconductor elements have a first surface and a second surface, which is opposite to the first surface, a die, a first RDL positioned on the first surface, and a second RDL positioned on the second surface. In FIG. 1, the first RDL 114 and the die 11 forms a fan-in structure whereas in FIG. 4, the first RDL 114 and the die 11 forms a fan-out structure.

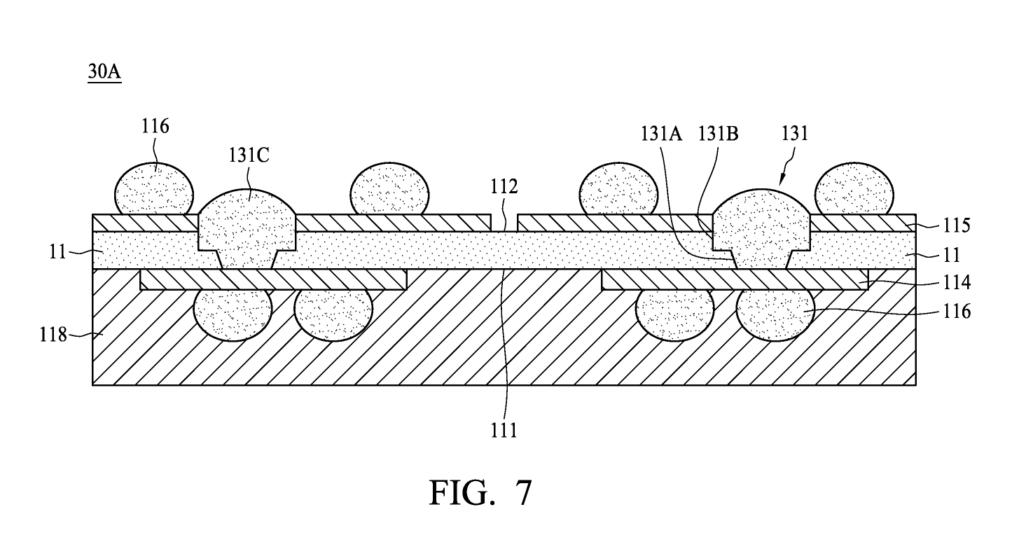

As shown in FIG. 2, after the first RDL 114 is sputtered on the first surface 111 of the die 11, at least one lead connector 116, or in this embodiment, a solder ball, is positioned on the first RDL 114 either by a ball dropping process or spraying the solder balls with the assistance of a fine-pitched stencil plate. At this stage of the process, neither the via is drilled in the die 11 nor the second RDL 115 is sputtered on the second surface 112. In the following step, as can be seen in FIG. 7, a layer of dry film 118 is adhered to the first surface 111, the lead connectors 116, and the first RDL 114 to form a supporting layer. The dry film 118 is processed to perfectly cover the contour of the first RDL 114 and the lead connectors 116 on the first surface 111 so as to form a seamless protection to the first surface 111 and the elements added thereon. The dry film 118 also provides a support to the first surface 111 since in the following procedure, the processing will occur on the second surface 112 of the semiconductor device 30A.

In the present embodiment, as shown in FIG. 7, a second RDL 115 is sputtered on the second surface 112 and a conductive via 131 is formed on the die 11 by a laser drilling process. The laser drilling process is utilized to penetrate through the second RDL 115 and the die 11 is positioned underneath, until the first RDL 114 is reached. After the formation of the conductive via 131, conductive materials are positioned into the conductive via 131 to electrically connect the first RDL 114 and the second RDL 115. In one embodiment, a reflow process is followed by the positioning of the conductive materials into the via in order to avoid the formation of any voids between the conductive materials and the inner wall of the via. In another embodiment, at least one lead connector 116 is positioned onto the second RDL 115 and the dry film 118 is removed by an etching, for instance, a wet-etching process, or a direct peeling process. The laser drilling process used in the present embodiment herein includes a UV laser drilling method and a UV laser scanning method. As can be seen in FIG. 7, the conductive via 131 possesses a tapered portion 131A and a planar portion 131B. The tapered portion 131 a is formed by a UV laser drilling method whereas the planar portion 131B is formed by a UV laser scanning method. Particularly, the UV laser drilling method creates a tapered shape in which the sizes of the two ends of the conductive via are different.

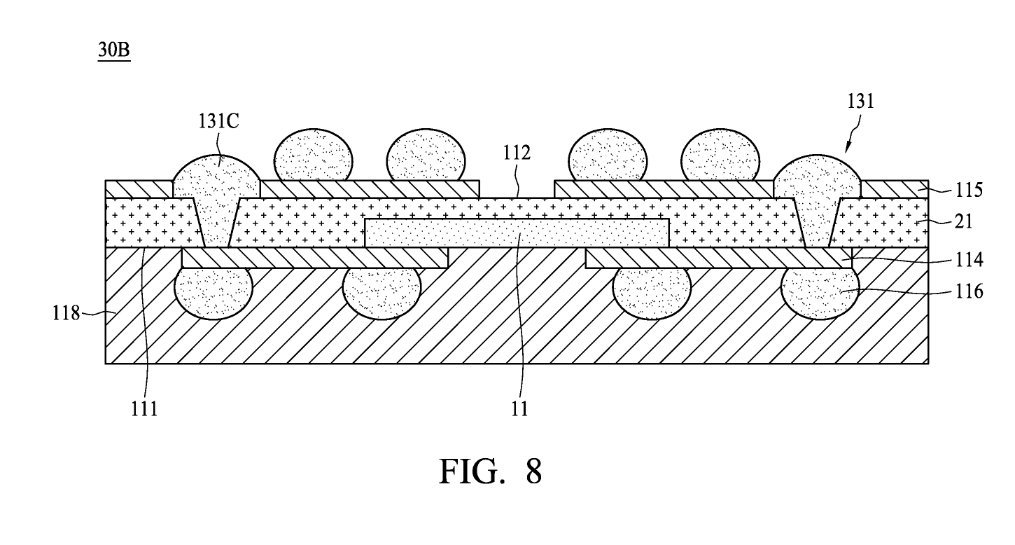

As shown in FIG. 5, a die 11 is first encapsulated by a molding compound 21. After the first RDL 114 is sputtered on the first surface 111 of the semiconductor device 20A, at least one lead connector 116, or in this embodiment, a solder ball, is positioned on the first RDL 114. At this stage of the process, neither the via 131 is formed on the die 11 nor the second RDL 115 is sputtered on the second surface 112 of the semiconductor device 20A. In the following step, as can be seen in FIG. 8, a layer of dry film 118 is adhered to the first surface 111, the lead connectors 116, and the first RDL 114 to form a supporting layer. The dry film 118 is processed to perfectly cover the contour of the first RDL 114 and the lead connectors 116 on the first surface 111 so as to form a seamless protection to the first surface 111 and the elements added thereon. The dry film 118 also provides a support to the first surface 111.

As shown in FIG. 8, a second RDL 115 is sputtered on the second 112 surface of the semiconductor device 30B, and the conductive via 131 is formed on the molding compound 21 by a laser drilling process. The laser drilling process is utilized to penetrate through the second RDL 115 and the molding compound 21 positioned underneath, until the first RDL 114 is reached. After the formation of the conductive via 131, conductive materials are positioned into the conductive via 131 to electrically connect the first RDL 114 and the second RDL 115. In one embodiment, the conductive materials can be preformed spheres, utilizing ball-dropping or ball-spaying to fill the preformed spheres into conductive via with the presence of fine-pitched stencil plate. The conductive materials can be, but not limited to, Cu, Sn, PbSn, or the combination thereof. In another embodiment, a reflow process is followed by the positioning of the conductive materials into the via 131 in order to avoid the formation of any voids between the conductive materials and the inner wall of the via 131. In another embodiment, after adhering the dry film 118, the second RDL 115, and the lead connector 116 on a wafer or a redistributed wafer (wafer redistributed with selected chips and with RDL), each die can be further separated by a cutting step. In another embodiment, at least one lead connector 116 is positioned onto the second RDL 115 and the dry film 118 is removed by an etching, for instance, a wet-etching process, or a direct peeling process. The laser drilling process used in the present embodiment herein includes a UV laser drilling mode, a UV laser scanning mode, and the combination thereof. As can be seen in FIG. 7, the conductive via 131 possesses a tapered portion 131A and a cylindrical portion 131B. The conductive via 131 can be formed by different drilling methods. For example, in the present embodiment, the tapered portion 131A is formed by a UV laser drilling mode, and the cylindrical portion 131B is formed by the UV laser scanning mode. Particularly, the UV laser drilling method creates a tapered shape in which the sizes of the two ends of the conductive via are different.

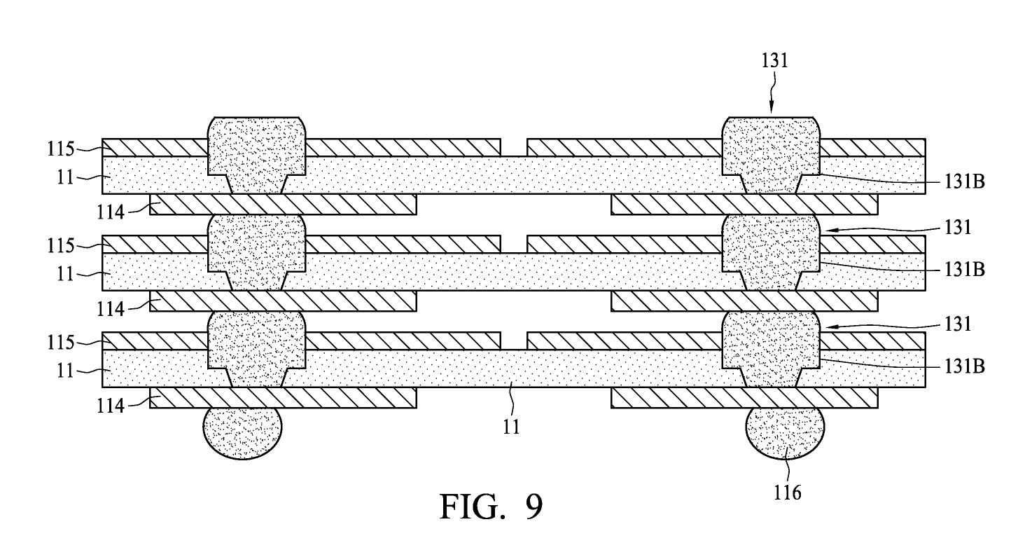

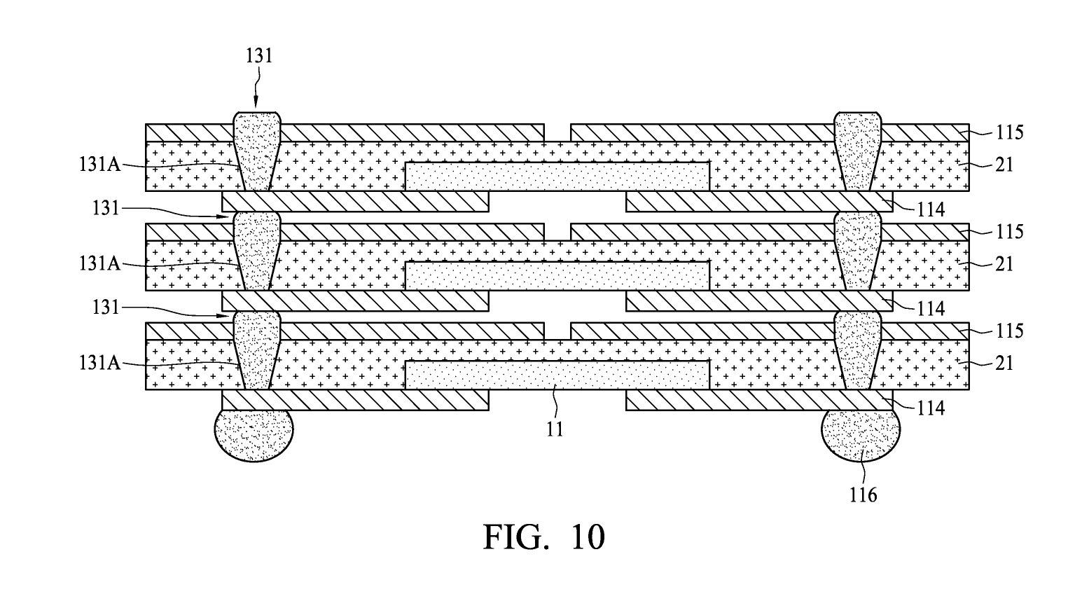

As shown in FIG. 9 and FIG. 10, a three-dimensional (3D) IC structure is formed by stacking three semiconductor devices 10 (see FIG. 1) and three semiconductor devices 20 (see FIG. 4) vertically on top of each other. Each semiconductor in the 3D IC structure can be electrically connected by the conductive via 131, the first RDL 114, and the second RDL 115. However, the 3D IC structure is not limited to the embodiment depicted in FIG. 9 and FIG. 10. Semiconductor devices with different layouts can be stacked onto each other to form a more complex 3D structure. In building a complex 3D structure, the position of the lead connectors 116 shall be designed with respect to each layer stacked. In another embodiment, semiconductor structures with different sizes can form one of the 3D IC structure described above. For example, a wafer-to-wafer bonding, a die-to-wafer bonding, or a die-to-die bonding. In addition, if copper or the alloy thereof is used as the conductive materials in the first/second RDL 114/115, the surface area of the copper can be increased in order to mitigate the heat dissipation problem appearing in the 3D IC structure because the copper possesses high thermal conductivity.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a semiconductor element having a first surface and a second surface opposite to the first surface, and the semiconductor element comprises:
a die;
a first redistribution layer positioned on the first surface; and
a second redistribution layer positioned on the second surface of the semiconductor element; and
a conductive via disposed on the semiconductor element, configured to electrically connect the first redistribution layer and the second redistribution layer, wherein the die can be electrically coupled to another semiconductor device through the conductive via.

2. The semiconductor device of claim 1, wherein the conductive via penetrates through the die.

3. The semiconductor device of claim 2, further comprising a lead connector positioned on the first and/or the second redistribution layer.

4. The semiconductor device of claim 1, wherein the space formed by the conductive via further comprises conductive materials.

5. The semiconductor device of claim 1, wherein the semiconductor element further comprises a molding compound adjacently positioned at some surfaces of the die.

6. The semiconductor device of claim 5, wherein the conductive via penetrates through the molding compound.

7. The semiconductor device of claim 6, further comprising a lead connector positioned on the first and/or the second redistribution layer.

8. A semiconductor device fabrication method, the method comprising:
providing a semiconductor element having a first surface and a second surface opposite to the first surface, and the semiconductor element comprises a die, a first redistribution layer positioned on the first surface, and a second redistribution layer positioned on the second surface; and
forming a conductive via in the semiconductor element to electrically couple the die to another semiconductor device, wherein the conductive via is extended from the second surface and is configured to electrically connect the first redistribution layer and the second redistribution layer, and wherein the sizes of the two ends of the via are different.

9. The semiconductor device fabrication method of claim 8, wherein the step of providing a semiconductor element further comprises:
forming at least one lead connector on the first surface; and
adhering a dry film to the first surface, the lead connector, and the first redistribution layer to form a supporting layer.

10. The semiconductor device fabrication method of claim 8, wherein the step of forming the conductive via comprises:
forming the conductive via on the die by laser drilling;
positioning conductive materials into the conductive via;
positioning at least one lead connector to the second redistribution layer; and
removing the dry film.

11. The semiconductor device fabrication method of claim 10, wherein the step removing the dry film comprises an etching process or a peeling process.

12. The semiconductor device fabrication method of claim 11, wherein the laser drilling process comprises an UV laser drilling method, an UV laser scanning method, or the combination thereof.

13. The semiconductor device fabrication method of claim 8, further comprising a step of forming a three-dimensional stacking structure by electrically coupling to another semiconductor structure through the semiconductor device.

14. The semiconductor device fabrication method of claim 8, wherein the step of providing a semiconductor element further comprises:
forming at least one lead connector on the first surface;
forming a molding compound adjacently disposed at partial surface of the die; and
adhering a dry film to the first surface, the lead connector, and the first redistribution layer to form a supporting layer.

15. The semiconductor device fabrication method of claim 8, wherein the step of forming the conductive via comprises:
forming the conductive via on the molding compound by laser drilling;
positioning conductive materials into the conductive via;
positioning at least one lead connector on the second redistribution layer, and
removing the dry film.

16. The semiconductor device fabrication method of claim 15, wherein the step or removing the dry film comprises an etching process of a peeling process.

17. The semiconductor device fabrication method of claim 15, wherein the step of laser drilling comprises a UV laser drilling method, a UV laser scanning method, or the combination thereof.

18. The semiconductor device fabrication method of claim 15, further comprising a step of forming a three-dimensional stacking structure by electrically coupling to another semiconductor structure through the semiconductor device.

19. The semiconductor device fabrication method of claim 8, wherein the step of positioning conductive materials into the conductive via further comprises a reflow process.
